(19) United States
(12) Patent Application Publication
(10) Pub. No.: US 2025/0344357 A1
(43) Pub. Date: Nov. 6, 2025

(54) Device For Connecting An Electrical Component To A Component To Be Electrically Insulated Therefrom, And Connection Assembly Comprising Such A Device

(71) Applicant: Eugen Forschner GmbH, Spaichingen (DE)

(72) Inventors: Martin Dopadlo, Spaichingen (DE); Xu Zhang, Spaichingen (DE); Henning Sdun, Spaichingen (DE); Matthias Goldsche, Spaichingen (DE)

(73) Assignee: Eugen Forschner GmbH, Spaichingen (DE)

(21) Appl. No.: 18/713,956

(22) PCT Filed: Nov. 28, 2022
(86) PCT No.: PCT/EP2022/083394

§ 371 Date: May 28, 2024

(30) Foreign Application Priority Data
Nov. 29, 2021 (DE) 10 2021 131 306.6
Dec. 17, 2021 (DE) 10 2021 133 689.9

(51) Int. Cl. H05K 7/20; H02G 5/10; H05K 7/14

(52) U.S. Cl. CPC H05K 7/209; H02G 5/10; H05K 7/14329; H05K 7/20445

(57) ABSTRACT

An apparatus for connecting an electrical component to an insulated component to be electrically insulated therefrom includes an electrically insulating heat transfer unit for transferring heat between the electrical component and the insulated component to be electrically insulated therefrom; an attachment unit for attaching the electrical component to the electrically insulating heat transfer unit; and an electrically insulating support for arranging the electrically insulating heat transfer unit on the insulated component. The attachment unit is overmolded with the electrically insulating heat transfer unit. The electrically insulating support is arranged on the electrically insulating heat transfer unit in such a way that the electrically insulating support presses the electrically insulating heat transfer unit against the insulated component.

### TECHNICAL FIELD

The present invention relates to an apparatus for connecting an electrical component to an insulated component to be electrically insulated therefrom. The electrical component is, for example, a busbar and/or a printed circuit board. The insulated component is, for example, a housing. The apparatus has an electrically insulating support, an electrically insulating heat transfer unit and an attachment unit.

The invention also relates to a connection assembly in which an electrical component, in particular a busbar, and an insulated component to be electrically insulated therefrom, in particular a housing, are connected to one another by an apparatus of the type mentioned above.

### BACKGROUND

An apparatus for connecting an electrical component to a housing is known from EP 2 871 921 B1. The apparatus comprises an electrically insulating body, a housing body and a busbar. The housing body and the electrically insulating body are integrally connected to each other. The busbar is embedded in the electrically insulating body. The connection assembly shown is therefore not configured to be non-destructively detachable from each other, which is a significant disadvantage for maintenance and/or repair work and for recycling.

Attempts have therefore been made to further develop this connection assembly. For example, WO 2020/156917 A1 shows such a connection assembly for connecting a busbar to a housing for electrical components. The connection assembly comprises the busbar and at least one wall of the housing as well as at least one electrically insulating element, wherein the connection assembly has at least one fastening element for connecting the electrically insulating element to the wall of the housing. However, even with this known connection assembly, there is still potential for improvement, in particular with regard to the heat dissipation of the busbar.

Based on the above prior art, it is an object of the present invention to provide an apparatus which eliminates the above problems and disadvantages of the prior art. In particular, it is a task of the present invention to provide an apparatus for connecting an electrical component to an insulated component, wherein the apparatus has improved heat dissipation.

### SUMMARY

The object is solved by an apparatus according to claim 1 and a connection assembly according to claim 15. Advantageous further embodiments of the invention are the subject of the dependent claims.

In particular, the solution is to provide an apparatus for connecting an electrical component to an insulated component to be electrically insulated from the electrical component, preferably in an electric vehicle, wherein the apparatus comprises: an electrically insulating heat transfer unit for transferring heat between the electrical component and the insulated component to be electrically insulated therefrom; an attachment unit for attaching the electrical component to the electrically insulating heat transfer unit; and an electrically insulating support or holder for arranging the electrically insulating heat transfer unit on the insulated component to be electrically insulated, wherein the attachment unit is overmolded with the electrically insulating heat transfer unit, and wherein the electrically insulating support is arranged on the electrically insulating heat transfer unit such that the electrically insulating support presses the electrically insulating heat transfer unit against the insulated component.

The electrical component can be, for example, a busbar, a conductor track and/or a printed circuit board. In particular, the electrical component is a high-voltage component. The insulated component can be, for example, a housing or a housing wall. In particular, the housing can be a housing for high-voltage components, for example a high-voltage junction box. Preferably, the high-voltage junction box is for an electric vehicle and is used in an electric vehicle.

The apparatus according to the invention thus comprises an electrically insulating support, an electrically insulating heat transfer unit and an attachment unit.

The support is configured to attach the electrical component to the insulated component. Furthermore, the support is configured to attach the electrically insulating heat transfer unit to the insulated component.

The electrically insulating heat transfer unit does not have to be attached directly to the insulated component, but can be attached indirectly by means of the electrically insulating support. A direct connection, for example a screw connection, is understood to be a connection in which the workpiece to be connected is itself equipped with a fastening region, for example with drilled holes or a thread. The fastening region is then used for direct fastening to the other component. Correspondingly, an indirect connection, for example a screw connection, is a connection in which the workpiece to be connected is fastened to the other component by means of an additional workpiece, for example a support with fastening regions.

This means that the choice of material for the heat transfer unit is more flexible, i.e. less restricted. In particular, materials with very good thermal conductivity can be used, which would actually be too brittle for direct fastening. In particular, materials can be used that would not be suitable for forming fastening regions.

In other words, the heat transfer unit is attached to the insulated component, preferably exclusively, via the fastening regions of the support. Preferably, the heat transfer unit therefore has no fastening regions of its own.

The electrically insulating support is preferably configured in one piece from an electrically insulating material. Irrespective of this, the support preferably has fastening regions to which the support is attached to the insulated component. Fastening to the fastening regions can, for example, be carried out using fastening elements such as screws and the like. Preferably, the support is configured in such a way that it accommodates or at least partially encloses the heat transfer unit.

This also allows the heat transfer unit to be easily replaced if the thermal conductivity of the apparatus needs to be adjusted. For this purpose, the heat transfer unit can be detached from the support, for example, and replaced with another heat transfer unit that has a different thermal conductivity.

The heat transfer unit is configured to transfer heat, i.e. thermal energy or thermal loads, from the electrical component or the attachment unit to the insulated component to be electrically insulated from the electrical component.

Preferably, the heat transfer unit and/or the support can have an anti-rotation device. The anti-rotation device is configured to prevent the heat transfer unit and the support from rotating relative to each other. For example, the anti-rotation device can have at least one protrusion on the heat transfer unit or on the support and a recess of complementary shape on the other element, i.e. the support or the heat transfer unit.

The attachment unit is preferably formed in one piece and can be directly connected to the electrical component. In addition, the attachment unit is overmolded with or by the heat transfer unit. This means that the attachment unit is connected to the electrically insulating heat transfer unit by overmolding the attachment unit with a material forming the electrically insulating heat transfer unit. The heat transfer unit is manufactured by injection molding and molded around the attachment unit in such a way that the heat transfer unit embeds the attachment unit. This achieves particularly good heat transfer between the attachment unit and the heat transfer unit. Preferably, an upper part of the attachment unit is exposed, i.e. not overmolded by the heat transfer unit. The attachment unit preferably makes contact with the electrical component at this upper part, which can be configured as a radially widened head in particular.

Due to its connection to the electrical component, the attachment unit is on the one hand suitable for attaching the electrical component to the heat transfer unit. On the other hand, the attachment unit is connected to the electrical component in a heat-communicating, i.e. heat-conducting, manner.

Overall, heat can therefore be dissipated from the electrical component through the attachment unit and then through the heat transfer unit to the insulated component.

Optionally, a thermally conductive sheet and/or preferably a thermally conductive paste can be arranged, for example, between the heat transfer unit and the insulated component.

Preferably, the attachment unit—namely in a state in which the heat transfer unit is arranged on the support—is arranged without contact, i.e. without direct contact with the support.

According to an advantageous further development of the invention, the attachment unit is connected to the heat transfer unit in a form-fitting manner.

As a result, a contact surface between the attachment unit and the heat transfer unit can be configured to be particularly large. This improves the retention of the attachment unit in the heat transfer unit, for example when a torque acts on the attachment unit—for example when attaching a fastening part to the attachment unit. This also improves the heat transfer between the attachment unit and the heat transfer unit.

The form-fitting can be configured using undercuts, for example. For example, the attachment unit has grooves and/or protrusions, in particular radial grooves and/or protrusions.

An advantageous further development of the invention provides for the support to be arranged on the heat transfer unit in such a way that the support spans the heat transfer unit.

The support is thus configured as a clamping element in such a way that the heat transfer unit can be clamped between the support and the insulated component for arranging the heat transfer unit on the insulated component.

The support is thus configured in such a way that it partially extends laterally beyond the heat transfer unit. Fastening regions can thus be configured on these lateral areas.

For example, the support can have at least two fastening regions, each of which projects beyond the heat transfer unit at least partially on one side of the heat transfer unit. In particular, the two fastening regions are arranged on two opposite sides of the heat transfer unit.

Preferably, the support can be connected to the insulated component in a form-fitting and/or force-fitting manner. For example, the support, in particular the fastening regions thereof, can have holes, in particular long holes, via which the support can be screwed to the insulated component. This has the advantage that the apparatus for connecting the electrical component to the insulated component to be electrically insulated from the electrical component can be easily mounted.

Spacer rings can also be arranged on the holes to secure the support. Preferably, the spacer rings are configured from steel. Furthermore, the spacer rings are preferably inserted into the support, in particular pressed in. Alternatively, they are used as insert rings. In general, the spacer rings make it possible to attach the support particularly securely to the insulated component. The spacer rings can prevent deformation, for example creep, of the support.

Preferably, the support can have a greater distance from the insulated component than the heat transfer unit. In particular, a gap can be formed between the support and the insulated component. In this way, the heat transfer unit can be pressed particularly securely against the insulated component.

In a further advantageous further development of the invention, the support has at least one first contact surface which is in contact with at least one second contact surface of the heat transfer unit for transmitting force between the support and the heat transfer unit.

The support presses the heat transfer unit against the insulated component via the contact surface.

An advantageous further development of the invention provides for the support to form a centering shape, which is formed by means of the at least one first contact surface.

The centering shape is designed in such a way that the heat transfer unit can be centered by the support. In particular, the heat transfer unit can be centered when the at least one first contact surface comes into contact with the at least one second contact surface. Preferably, the centering shape is formed by means of at least one inclined contact surface. For example, the support may have two inclined first contact surfaces that are inclined towards each other. The two contact surfaces thus have an angle, and explicitly not 0° or 90°, to a plane that runs parallel to the plane of extension of the insulated component.

In an advantageous further development of the invention, the support has a passage and the heat transfer unit and/or the attachment unit are arranged on the support in such a way that the heat transfer unit and/or the attachment unit are arranged at least partially in the passage.

Thus, the support at least partially surrounds the heat transfer unit and/or the attachment unit. This makes it particularly easy to attach the heat transfer unit to the insulated component. If the support has the centering shape, the heat transfer unit is preferably centered in the passage.

According to an advantageous further development of the invention, the attachment unit extends through the passage, whereby a clearance, in particular a radial clearance, is formed between the attachment unit and the support.

In this way, the support and the attachment unit can be formed without contact. This creates a gap, in particular an insulation gap, between the two elements. In particular, the attachment unit extends through the support in the axial direction of the attachment unit.

In an advantageous further development of the invention, the attachment unit extends beyond the support through the passage.

The attachment unit thus protrudes beyond the support and is higher than the support when viewed in the axial direction of the attachment unit. This prevents direct contact between the support and the electrical component. A gap, in particular an insulating gap, is therefore also formed between the two elements.

In an advantageous further development of the invention, the support and the heat transfer unit are connected to one another in a form-fitting manner, in particular by means of a detachable snap-fit connector.

This significantly improves handling during assembly, as the heat transfer unit is held by the support. Especially in combination with the centering shape, the apparatus can be attached quickly and precisely to the insulated component to be electrically insulated.

For example, the heat transfer unit can be connected to the support by means of a detachable snap-fit connector. For example, the heat transfer unit comprises at least one mating part for this purpose, which engages in at least one snap-in groove or a latching bracket of the support—or vice versa—when the support is connected to the heat transfer unit. The mating part can be designed in such a way that it deforms elastically during the connection and engages in the snap-in groove or the latching bracket when the support and the heat transfer unit are positioned in the desired position relative to each other. To release the connection between the support and the heat transfer unit, the mating part can preferably be released from engagement with the snap-in groove or the latching bracket by elastic deformation.

According to an advantageous further development of the invention, the support and the heat transfer unit are made of an electrically insulating plastic.

This has the advantage that the support and the heat transfer unit can be manufactured simply and cost-effectively. Irrespective of this, the support can simply be designed as a lightweight component. For example, the support comprises weight-reducing structures.

An advantageous further development of the invention provides that the support is designed to be thermally insulating or has a lower thermal conductivity than the heat transfer unit.

The electrically insulating support can thus be designed to be thermally insulating. This means that the support is preferably hardly suitable for transferring thermal energy. This has the advantage that the overall thermal conductivity of the apparatus depends almost exclusively on the thermal conductivity of the heat transfer unit. If the overall thermal conductivity of the apparatus is predetermined, the heat transfer unit can be adapted accordingly without having to take the thermal conductivity of the support into account. Alternatively, the support has a significantly lower thermal conductivity than the heat transfer unit. This means that the thermal conductivity of the support is 70% lower in relation to the thermal conductivity of the heat transfer unit, preferably 80% lower and particularly preferably 90% lower.

In a further advantageous further development of the invention, the heat transfer unit has a thermal conductivity of more than 1.5 W/(m·K), preferably more than about 4 W/(m·K), particularly preferably more than 9 W/(m·K).

The electrically insulating heat transfer unit is preferably made of a material with very good thermal conductivity, in particular a plastic with very good thermal conductivity. The material of the heat transfer unit can be thermoplastics, thermosets or elastomers. In particular, the material can be polypropylene (PP), polyphthalamide (PPA), polyamide (especially PA 6, PA 66 or PA 12), thermoplastic copolyesters (COPE), polyphenylene sulphide (PPS), liquid crystal polymer (LCP), thermoplastic elastomers (TPE), polycarbonates/acrylonitrile butadiene styrene (PC/ABS blend), polyether ether ketone (PEEK), polyetherimide (PEI) or polybutylene terephthalate (PBT). A ceramic and/or mineral filler can be added to these plastics to improve their thermal conductivity. Aluminum oxide or boron nitride are particularly suitable for this purpose. The material of the heat transfer unit is particularly preferably based on PA6, PA12 or PBT.

According to an advantageous further development of the invention, the attachment unit is made of a metallic material with a particularly high thermal conductivity of over 50 W/(m·K), preferably over 100 W/(m·K), in particular made of brass.

An advantageous further development of the invention provides that the attachment unit has a hole, in particular a blind hole, with a threaded device or latching device.

Thus, the attachment unit has a recess or a blind hole with a threaded device or latching device with which a fastening part, for example a screw, can be engaged. The electrical component is then preferably sandwiched between the fastening part and the attachment unit. Of course, two or more electrical components can also be arranged on the attachment unit.

The initial object is also solved by a connection assembly which has the following: an electrical component, in particular a busbar; an insulated component, in particular a housing; and one of the apparatus described above for connecting the electrical component to the insulated component to be electrically insulated from the electrical component, the electrical component and the insulated component being connected to one another, in particular detachably, via the apparatus.

Preferably, the busbar forms the electrical component in the connection assembly. The housing can be the insulated component to be electrically insulated from the busbar.

Particularly advantageously, the apparatus according to the invention can be used to arrange an electrical component, in particular a high-voltage component, inside a housing, in particular a high-voltage distributor housing. For example, an electrical component designed as a high-voltage fuse and/or a busbar connected to the high-voltage fuse can be arranged on the high-voltage distributor housing wall in such a way that the apparatus according to the invention can be used not only for mechanical attachment to the high-voltage distributor housing wall, but also for heat dissipation to the high-voltage distributor housing wall, in particular targeted heat dissipation of heat generated in the high-voltage fuse. With its large surface area, the high-voltage distributor housing wall serves as a suitable heat sink from which the heat can be further dissipated.

In the use described above, the apparatus according to the invention is well suited to dissipating the power loss generated in the charging path of the high-voltage fuse as heat.

### BRIEF DESCRIPTION OF THE DRAWINGS

The different and exemplary features described above can be combined with one another according to the invention, insofar as this is technically sensible and suitable. Further features, advantages and embodiments of the invention are shown in the following description of embodiments and with reference to the drawings. The drawings show

FIG. 1 a perspective view of an embodiment of an apparatus for connecting an electrical component to an insulated component to be electrically insulated therefrom; and

FIG. 2 a sectional view of a connection arrangement according to the invention with the apparatus shown in FIG. 1.

### DETAILED DESCRIPTION

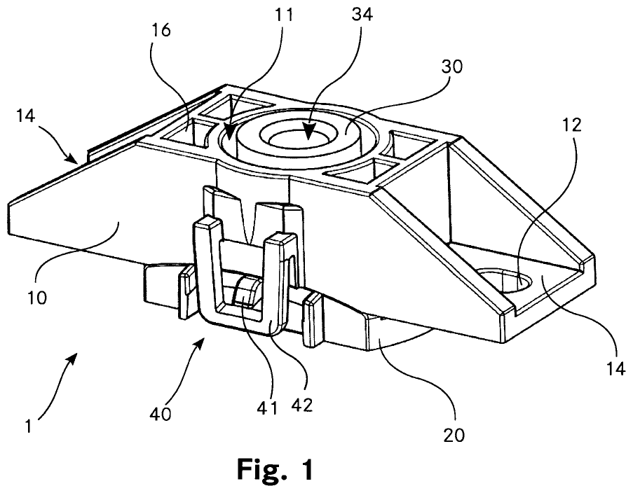

FIG. 1 shows a perspective view of an embodiment of an apparatus 1 for connecting an electrical component 100, which is not shown, to an insulated component 200 to be electrically insulated therefrom. The electrical component 100 can be, for example, a busbar 100 and/or a circuit board 100. The insulated component 200 to be electrically insulated from the electrical component 100, also called insulated component 200 for short, can for example be a housing 200 or a wall thereof, to which the electrical component 100 is to be attached.

The apparatus 1 comprises an electrically insulating support 10, an electrically insulating heat transfer unit 20 and an attachment unit 30. The attachment unit 30 is connected to the heat transfer unit 20 via a snap-fit connector 40. As shown in FIG. 1, the heat transfer unit 20 can have a mating part 41 and the support 10 can have a latching bracket 42. The snap-fit connector 40 serves to improve the handling of the apparatus 1 during assembly. A further snap-fit connector 40 is formed symmetrically on the opposite side of the apparatus 1 not visible in FIG. 1.

During assembly, the apparatus 1 is attached to the insulated component 200. For this purpose, the support 10 has two fastening regions 14. In this case, the two fastening regions 14 have holes 12. In particular, the holes 12 are arranged symmetrically on the support 10 and are formed as long holes 12. In order to be able to fasten the support 10 to the insulated component 200, fastening elements such as screws and/or rivets or bolts can be passed through the holes 12 and fixed to the insulated component 200.

The two fastening regions 14 span or protrude over the heat transfer unit 20, which means that the heat transfer unit 20 can also be fixed by means of the support 10. In the embodiment of the apparatus 1 shown in FIG. 1, the support 10 is designed as a lightweight component. For this purpose, the support 10 comprises a support structure with recesses 16 and reinforcements. Due to the support structure, the support 10 has the necessary rigidity to be able to attach the apparatus 1 to the insulated component 200. In particular, the support structure is a stiffening structure.

The support 10 has a passage 11. As indicated in FIG. 1, the attachment unit 30 protrudes through the support 10, in particular its passage 11. A hole 34 is also arranged in the attachment unit 30. The hole 34 can serve to fasten a fastening part. Preferably, the attachment unit 30 can be screwed to the electrical component 100. Alternatively, the attachment unit 30 can be materially connected to the electrical component 100, in particular via a connection area or a coupling surface of the attachment unit 30. For example, the attachment unit 30 can be bonded or welded to the electrical component 100, in particular via the coupling surface.

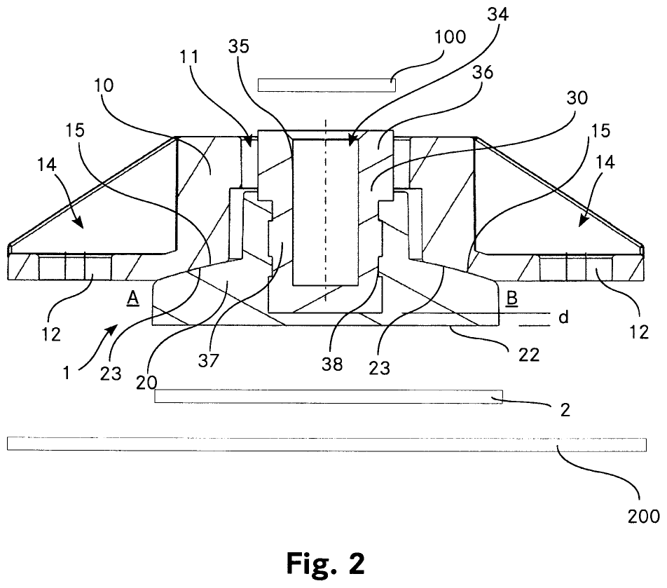

FIG. 2 shows a sectional view of a connection assembly according to the invention with the apparatus 1 shown in FIG. 1. The electrical component 100 or the busbar 100 and insulated component 200 or the housing 200 are also shown schematically.

FIG. 2 shows, in particular, closer details of the heat transfer unit 20 and the attachment unit 30. The attachment unit 30 is overmolded by the heat transfer unit 20 at least in a partial area. Thus, the attachment unit 30 is at least partially embedded in the heat transfer unit 20. In particular, the attachment unit 30 is arranged in a form-fitting manner in the heat transfer unit 20. For this purpose, the attachment unit 30 has several annular grooves 38.

The attachment unit 30 has a sleeve-like design. The attachment unit 30 has the hole 34 for fastening with the fastening part. For example, the hole 34 can have a threaded or latching device 35 for this purpose. The sleeve-like attachment unit 30 has a head 36, the upper area of which can be connected to the electrical component 100. As the head 36 is enlarged, heat can be dissipated particularly well from the electrical component 100. A shaft 37 is connected below the head 36.

The shaft 37 is embedded in the heat transfer unit 20. Grooves 38 are formed in the shaft 37. The attachment unit 30, in particular the shaft 37, extends downwardly into the heat transfer unit 20, but not through the heat transfer unit 20. Rather, a region with a thickness d is formed between an end region of the attachment unit 30, in particular between the end of the shaft 37, and a heat transfer surface 22 of the heat transfer unit 20 to the insulated component 200. The region can have a thickness of 1 to 2 mm, in particular about 1.4 mm, for example. This achieves sufficient electrical insulation on the one hand and sufficient heat dissipation on the other.

As can be clearly seen in FIG. 2, the heat transfer unit 20 protrudes beyond the support 10 at the bottom. This allows the heat transfer unit 20 to be pressed particularly well against the insulated component 200. Irrespective of the previous aspects, a thermally conductive sheet 2 and/or a thermally conductive paste 2 can be formed between the heat transfer unit 20 and the insulated component 200 to be electrically insulated. The thermally conductive sheet 2 has the advantage that it can compensate for tolerances in height due to its layer thickness. The heat-conducting paste 2 has the advantage that it compensates for unevenness in the heat transfer unit 20 when the heat transfer unit 20 is arranged on the insulated component 200 to be electrically insulated. Such unevenness is caused in particular by injection molding of the heat transfer unit 20. The heat-conducting paste 2 therefore represents a part of a preferred embodiment, in particular in the case of a heat transfer unit 20 manufactured by injection molding.

The attachment unit 30 also protrudes beyond the support 10, i.e. it is higher than the support 10. In this way, the electrical component 100 can be attached to the attachment unit 30 without coming into contact with the support 10. The attachment unit 30 is arranged in the passage 11 in such a way that a clearance, in particular a radial clearance, is formed between the attachment unit 30 and the passage 11. Thus, there is preferably no direct contact between the attachment unit 30 and the support 10.

FIG. 2 also shows the two fastening regions 14 with the two holes 12 of the support 10, which serve to press the heat transfer unit 20 against the insulated component 200 or to fasten it to the latter. In particular, a first of the two fastening regions 14 is arranged on a side A and a second of the two fastening regions 14 is arranged on a side B of the apparatus 1.

The support 10 has a first contact surface 15 and the heat transfer unit 20 has a second contact surface 23. In particular, the support 10 has two first contact surfaces 15 inclined towards each other and the heat transfer unit 20 correspondingly also has two second contact surfaces 23 inclined towards each other. Preferably, a first of the first contact surfaces 15 is arranged on side A and a second of the first contact surfaces 15 is arranged on side B of the apparatus 1. Similarly, a first of the second contact surfaces 23 is preferably arranged on side A and a second of the second contact surfaces 23 is preferably arranged on side B of the apparatus 1.

At the first contact surfaces 15 and second contact surface 23, the contact pressure is transmitted from the support 10 to the heat transfer unit 20. In addition, the contact surfaces 15, 23 are also designed as a centering form. Due to their inclined design, the first contact surface 15 and also the second contact surface 23 ensure centering of the heat transfer unit 20 and thus also of the attachment unit 30 within the support 10 and in particular within the passage 11 of the support 10.

The heat transfer unit 20 is pedestal-shaped. Here, the heat transfer unit 20 has a widened base area, on which the second contact surfaces 23 are also formed. In a central area, the heat transfer unit 20 has a cylindrical, upwardly extending area in which the attachment unit 30 is embedded.

It should be noted that the features of the invention described with reference to individual embodiments or variants, such as the type and configuration of the individual components and their precise dimensioning and spatial arrangement, may also be present in other embodiments, unless otherwise indicated or if this is prohibited for technical reasons. Furthermore, of such features of individual embodiments described in combination, not all features need necessarily be realized in a respective embodiment.

### List of Reference Signs

1 apparatus
2 thermally conductive sheet or thermal paste
10 support
11 passage
12 hole
14 fastening region
15 first contact surface
16 recess
20 heat transfer unit
22 heat transfer surface
23 second contact surface
30 attachment unit
34 hole
35 threaded device or latching device
36 head
37 shaft
38 groove
40 snap-fit connector
41 mating part
42 latching bracket
100 electrical component
200 (electrically) insulated component or component to be electrically insulated
d Thickness d of the heat transfer unit

1. An apparatus for connecting an electrical component to an insulated component to be electrically insulated therefrom, the apparatus comprising:
an electrically insulating heat transfer unit for transferring heat between the electrical component and the insulated component to be electrically insulated therefrom;
an attachment unit for attaching the electrical component to the electrically insulating heat transfer unit; and
an electrically insulating support for arranging the electrically insulating heat transfer unit on the insulated component,
wherein the attachment unit is overmolded with the electrically insulating heat transfer unit, and
wherein the electrically insulating support is arranged on the electrically insulating heat transfer unit in such a way that the electrically insulating support presses the electrically insulating heat transfer unit against the insulated component.

2. The apparatus according to claim 1, wherein the attachment unit is connected to the heat transfer unit in a form-fitting manner.

3. The apparatus according to claim 1, wherein the electrically insulating support is arranged on the electrically insulating heat transfer unit in such a way that the electrically insulating support spans the electrically insulating heat transfer unit.

4. The apparatus according to claim 1, wherein the support comprises at least one first contact surface in contact with at least one second contact surface of the heat transfer unit for transmitting force between the support and the heat transfer unit.

5. The apparatus according to claim 4, wherein the support forms a centering shape configured by the at least one first contact surface.

6. The apparatus according to claim 1, wherein the support comprises a passage and the heat transfer unit and/or the attachment unit are arranged on the support in such a way that the heat transfer unit and/or the attachment unit are arranged at least partially in the passage.

7. The apparatus according to claim 6, wherein the attachment unit extends through the passage and wherein a clearance, is arranged between the attachment unit and the support.

8. The apparatus according to claim 6, wherein the attachment unit extends through the passage beyond the support.

9. The apparatus according to claim 1, wherein the support and the heat transfer unit are connected to each other in a form-fitting manner.

10. The apparatus according to claim 1, wherein the support and the heat transfer unit are made of an electrically insulating plastic.

11. The apparatus according to claim 1, wherein the support is configured to be thermally insulating or has a lower thermal conductivity than a thermal conductivity of the heat transfer unit.

12. The apparatus according to claim 1, wherein the heat transfer unit has a thermal conductivity of more than 1.5 W/(m·K).

13. The apparatus according to claim 1, wherein the attachment unit is configured from a metallic material with a high thermal conductivity of more than 50 W/(m·K).

14. The apparatus according to claim 1, wherein the attachment unit has a hole with a threaded or latching device.

15. A connection assembly, comprising:
a) an electrical component;
b) an insulated component; and
c) an apparatus according to claim 1, wherein the electrical component and the insulated component are connected to each other, by the apparatus.

16. The connection assembly according to claim 15, wherein the electrical component is a busbar; and
Wherein the insulated component is a housing.

17. The apparatus according to claim 7, wherein the clearance is a radial clearance.

18. The apparatus according to claim 9, further comprising a releasable snap fit connector connecting the support and the heat transfer unit in a form-fitting manner.

19. The apparatus according to claim 13, wherein the metallic material is brass.

20. The apparatus according to claim 14, wherein the hole is a blind hole.
